(19) United States
(12) Patent Application Publication
(10) Pub. No.: US 2025/0040212 A1
(43) Pub. Date: Jan. 30, 2025

(54) NITRIDE SEMICONDUCTOR DEVICE

(71) Applicant: ROHM CO., LTD., Kyoto-shi (JP)

(72) Inventor: Takuya KITO, Kyoto-shi (JP)

(73) Assignee: ROHM CO., LTD., Kyoto-shi (JP)

(21) Appl. No.: 18/772,348

(22) Filed: Jul. 15, 2024

(30) Foreign Application Priority Data
Jul. 25, 2023 (JP) 2023-120836

(51) Int. Cl. H01L 29/20; H01L 29/10; H01L 29/15; H01L 29/205; H01L 29/778

(52) U.S. Cl. CPC H01L 29/2003; H01L 29/1066; H01L 29/151; H01L 29/205; H01L 29/7787

(57) ABSTRACT

A nitride semiconductor device includes a nitride semiconductor layer including a first superlattice buffer layer, a second superlattice buffer layer formed above the first superlattice buffer layer, an electron transit layer formed above the second superlattice buffer layer and composed of a first nitride semiconductor, and an electron supply layer formed above the electron transit layer and composed of a second nitride semiconductor. The first superlattice buffer layer has a first superlattice structure including a first layer and a second layer alternately arranged. The first layer is composed of AlₓGa₁₋ₓN, where 0<x<1. The second layer is composed of GaN. The second superlattice buffer layer has a second superlattice structure including a third layer and a fourth layer alternately arranged. The third layer is composed of Al_{y}Ga_{1-y}N, where 0<y<x. The fourth layer is composed of GaN.

### CROSS-REFERENCE TO RELATED APPLICATION

This application is based upon and claims the benefit of priority from prior Japanese Patent Application No. 2023-120836, filed on Jul. 25, 2023, the entire contents of which are incorporated herein by reference.

### BACKGROUND

### 1. Field

The present disclosure relates to a nitride semiconductor device.

### 2. Description of Related Art

High-electron-mobility transistors (HEMTs) are now being commercialized. A HEMT is one type of field effect transistor (FET) that uses a group III semiconductor such as gallium nitride (GaN). A HEMT uses two-dimensional electron gas (2DEG), formed near a semiconductor heterojunction interface, as a conduction path (channel). A power device using a HEMT has a lower ON resistance and is operable at a higher frequency than a typical silicon (Si) power device.

Japanese Laid-Open Patent Publication No. 2017-73506 describes an example of a nitride semiconductor device that includes a silicon substrate, an electron transit layer that is composed of a gallium nitride (GaN) layer, and an electron supply layer that is composed of an aluminum gallium nitride (AlGaN) layer. Two-dimensional electron gas (2DEG) is formed in the electron transit layer near the heterojunction interface of the electron transit layer and the electron supply layer. In the nitride semiconductor device of Japanese Laid-Open Patent Publication No. 2017-73506, a GaN layer (p-type GaN layer) doped with an acceptor impurity is located on the electron supply layer immediately below a gate electrode. In this structure, the p-type GaN layer increases the energy level of the conduction band near the heterojunction interface between the electron transit layer and the electron supply layer in a region immediately below the p-type GaN layer, thereby dispersing the channel located immediately below the p-type GaN layer. Thus, the normally-off operation of the nitride semiconductor device is achieved.

### BRIEF DESCRIPTION OF THE DRAWINGS

FIG. 1 is a schematic plan view showing a first embodiment of an exemplary nitride semiconductor device.

FIG. 2 is an enlarged plan view of the nitride semiconductor device shown in FIG. 1.

FIG. 3 is a schematic cross-sectional view of the nitride semiconductor device taken along line F3-F3 in FIG. 2.

FIG. 4 is a schematic diagram showing a stacking structure of a portion of a nitride semiconductor layer formed above a semiconductor substrate.

FIG. 5 is a schematic diagram showing a mechanism of eliminating dislocation lines using a superlattice structure.

FIG. 6 is a schematic diagram showing a stacking structure of a portion of a nitride semiconductor layer formed above a semiconductor substrate in a first modified example.

FIG. 7 is a schematic diagram showing a stacking structure of a portion of a nitride semiconductor layer formed above a semiconductor substrate in a second modified example.

FIG. 8 is a schematic diagram showing a stacking structure of a portion of a nitride semiconductor layer formed above a semiconductor substrate in a third modified example.

FIG. 9 is a schematic cross-sectional view showing a second embodiment of a nitride semiconductor device.

FIG. 10 is a schematic diagram showing a stacking structure of a portion of a nitride semiconductor layer formed above a semiconductor substrate.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

### First Embodiment

### Schematic Structure of Nitride Semiconductor Device

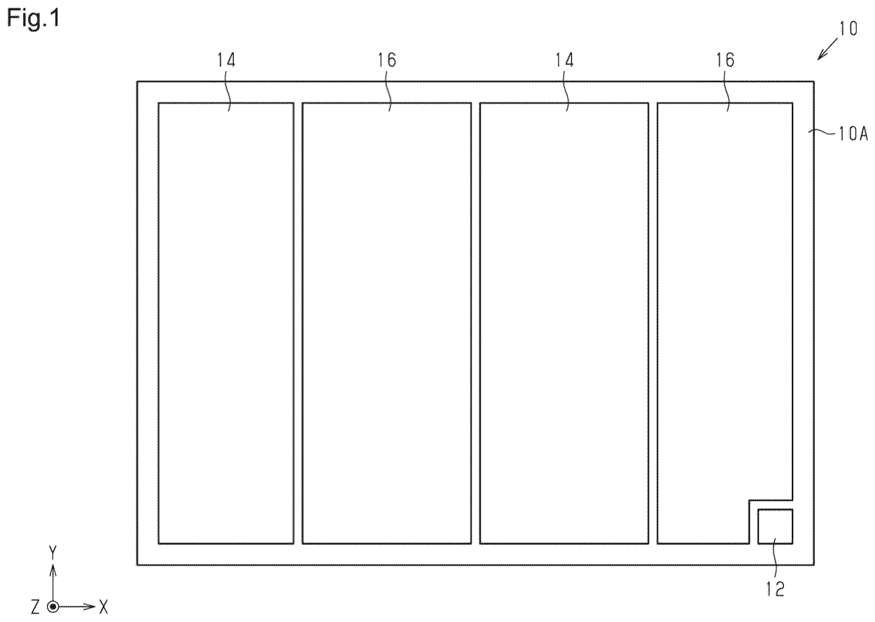

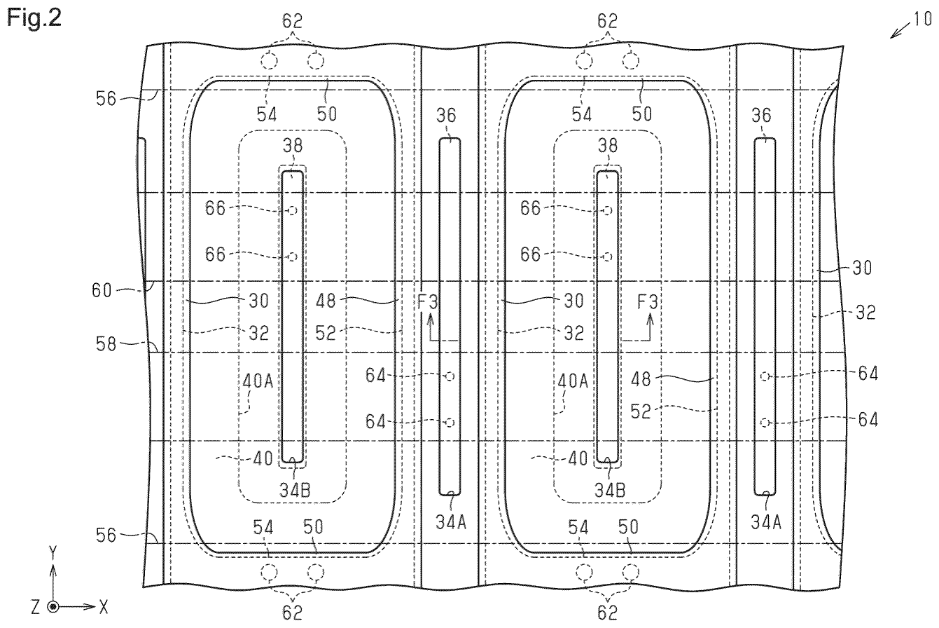

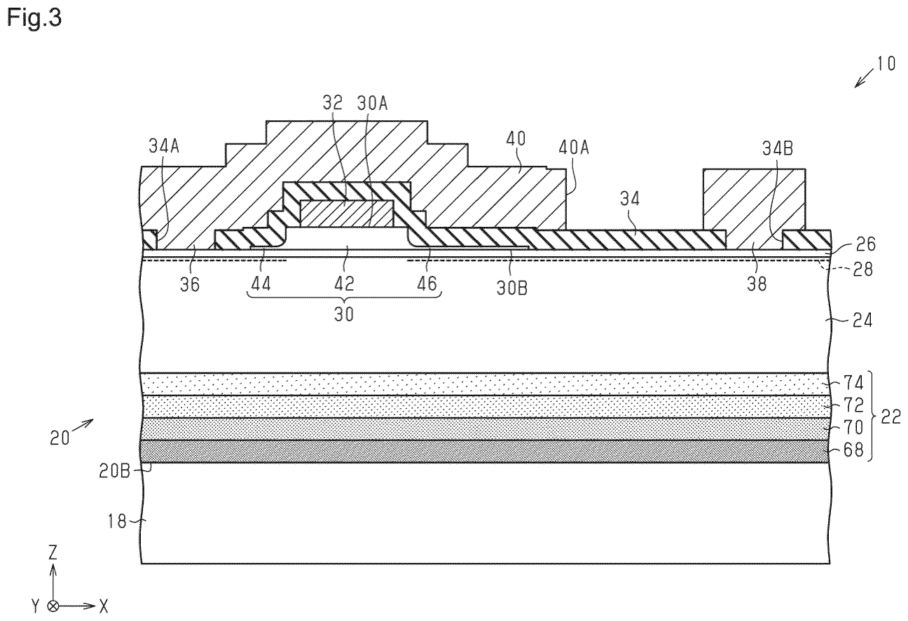

A schematic structure of an exemplary nitride semiconductor device 10 in accordance with a first embodiment will now be described with reference to FIGS. 1 to 3. In the present embodiment, the nitride semiconductor device 10 may be a semiconductor chip in which a high-electron-mobility transistor (HEMT) is formed. FIG. 1 is a schematic plan view of the exemplary nitride semiconductor device 10. FIG. 2 is an enlarged plan view of the nitride semiconductor device 10. FIG. 3 is a schematic cross-sectional view of the nitride semiconductor device 10 taken along line F3-F3 in FIG. 2.

In FIGS. 1 to 3, XYZ-axes are orthogonal to each other. The Z-axis direction is orthogonal to a surface of a semiconductor substrate 18 (refer to FIG. 3). The term “plan view” used in this specification refers to a view of the nitride semiconductor device 10 in the Z-axis direction from above unless otherwise specifically described.

As shown in FIG. 1, the nitride semiconductor device 10 may include an upper surface 10A that is rectangular in plan view and may include a gate pad 12, a source pad 14, and a drain pad 16 that are formed on the upper surface 10A. The gate pad 12, the source pad 14, and the drain pad 16 may be respectively electrically connected to a gate electrode, a source electrode, and a drain electrode of an HEMT formed in a semiconductor chip (e.g., gate electrode 32, source electrode 36, and drain electrode 38 shown in FIG. 2). The gate pad 12, the source pad 14, and the drain pad 16 may include external connection terminals of the nitride semiconductor device 10.

In the example shown in FIG. 1, the nitride semiconductor device 10 includes multiple source pads 14 and multiple drain pads 16. The source pads 14 and the drain pads 16 are alternately arranged in the X-axis direction. The number of pads 12, 14, 16 arranged on the upper surface 10A may be set in any manner in accordance with the necessity of a specified application.

The layout of the gate pad 12, the source pad 14, and the drain pad 16 is not limited to that in the example shown in FIG. 1. The gate pad 12, the source pad 14, and the drain pad 16 may be arranged in any alternative layout.

FIG. 3 is a schematic diagram showing a cross-section of an active region of an HEMT located below the source pad 14 or the drain pad 16 shown in FIG. 1. As shown in FIG. 3, the nitride semiconductor device 10 includes the semiconductor substrate 18 and a nitride semiconductor layer 20 formed above the semiconductor substrate 18. In the present disclosure, the term “above” includes the meaning of “on” in addition to “above” unless otherwise explicitly described. More specifically, the phrase “first layer formed above second layer” includes a structure in which the first layer may be in contact with the second layer and directly on the first second layer in one embodiment and a structure in which another layer may be formed between the first layer and the second layer in another embodiment.

The semiconductor substrate 18 may be formed from silicon (Si), silicon carbide (SiC), sapphire (Al₂O₃), or other substrate materials. The semiconductor substrate 18 may be composed of a material that differs from the nitride semiconductor layer 20. In an example, the semiconductor substrate 18 may be a Si substrate, particularly, a Si substrate having a (111) growth surface. The semiconductor substrate 18 may have an off-angle that is greater than 0°. The off-angle of the semiconductor substrate 18 may be greater than 0° and less than or equal to 1°. The semiconductor substrate 18 may have a thickness, for example, in a range of 200 μm to 1500 μm.

The nitride semiconductor layer 20 may include a buffer layer 22 formed above the semiconductor substrate 18, an electron transit layer 24 formed above the buffer layer 22, and an electron supply layer 26 formed above the electron transit layer 24. In the present embodiment, the nitride semiconductor layer 20 may include a bottom surface 20B in contact with the semiconductor substrate 18. The bottom surface 20B of the nitride semiconductor layer 20 may be included in the buffer layer 22.

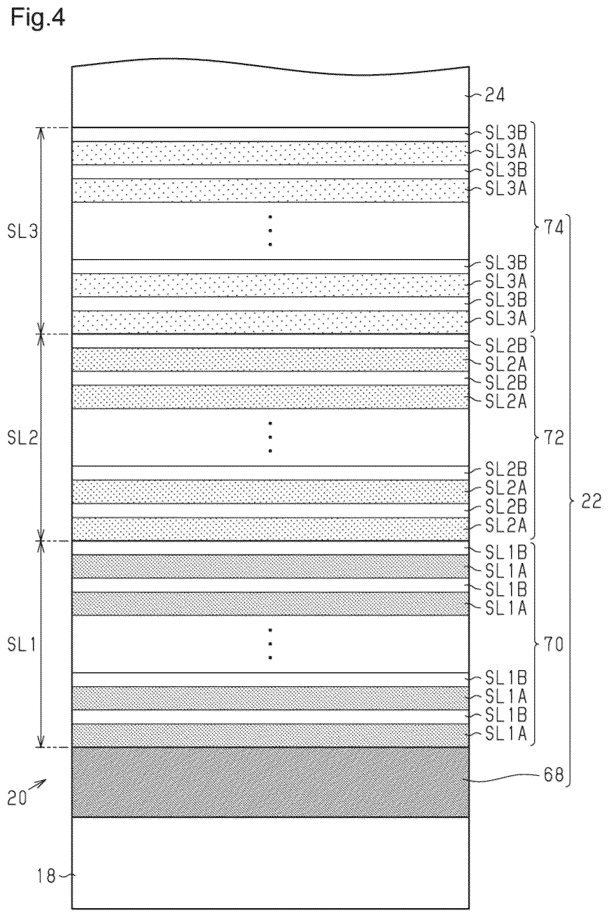

The buffer layer 22 may include one or more layers composed of a nitride semiconductor. The buffer layer 22 may be composed of any material that limits bending and formation of cracks caused by a difference in thermal expansion coefficient between the semiconductor substrate 18 and a layer formed above the buffer layer 22 (e.g., the electron transit layer 24 and the electron supply layer 26). The detail of the buffer layer 22 will be described later with reference to FIG. 4.

The electron transit layer 24 may be in contact with the buffer layer 22. The electron transit layer 24 is composed of a first nitride semiconductor. The first nitride semiconductor may include GaN. In the present embodiment, the first nitride semiconductor may include GaN as a main component. The electron transit layer 24 may have a thickness that is, for example in a range of 0.5 μm to 2 μm. Preferably, the thickness of the electron transit layer 24 may be less than or equal to 760 nm. More preferably, the thickness of the electron transit layer 24 may be in a range of 500 nm to 760 nm.

To inhibit current leakage in the electron transit layer 24, a portion of the electron transit layer 24 may be doped with an impurity so that the electron transit layer 24 excluding an outer layer region becomes semi-insulating. In this case, the impurity may be, for example, C. The concentration of the impurity in the electron transit layer 24 may be, for example, greater than or equal to 4×10¹⁶ cm⁻³. More specifically, the electron transit layer 24 may include GaN layers having different impurity concentrations, for example, a C-doped

GaN layer and a non-doped GaN layer. In this case, the C-doped GaN layer may be in contact with the buffer layer 22. The C-doped GaN layer may have a thickness in a range of 0.3 μm to 2 μm. The C concentration in the C-doped GaN layer may be in a range of 5×10¹⁷ cm⁻³ to 9×10¹⁹ cm⁻³. The non-doped GaN layer may be formed on the C-doped GaN layer and may have a thickness in a range of 0.05 μm to 0.4 μm. The non-doped GaN layer may be in contact with the electron supply layer 26. In an example, the electron transit layer 24 may include a C-doped GaN layer having a thickness of 0.4 μm and a non-doped GaN layer having a thickness of 0.4 μm. The C concentration in the C-doped GaN layer may be approximately 2×10¹⁹ cm⁻³.

The electron supply layer 26 is composed of a second nitride semiconductor having a larger bandgap than the first nitride semiconductor. The second nitride semiconductor may include AlGaN. In the present embodiment, the second nitride semiconductor may include AlGaN as a main component. In an example, the electron supply layer 26 is composed of AlₐGa₁₋ₐN, where 0.1<a<0.4, and, preferably, 0.1<a<0.3. The electron supply layer 26 may have a thickness in a range of 5 nm to 20 nm. Preferably, the thickness of the electron supply layer 26 may be greater than or equal to 8 nm.

The first nitride semiconductor (e.g., GaN), which forms the electron transit layer 24, differs in lattice constant from the second nitride semiconductor (e.g., AlGaN), which forms the electron supply layer 26. Thus, the electron transit layer 24 and the electron supply layer 26 form a lattice-mismatched heterojunction. The energy level of the conduction band of the electron transit layer 24 in the vicinity of the heterojunction interface is lower than the Fermi level due to spontaneous polarization of the electron transit layer 24 and the electron supply layer 26 and piezoelectric polarization caused by crystal strain in the vicinity of the heterojunction interface. As a result, two-dimensional electron gas 28 (2DEG) spreads in the electron transit layer 24 at a location close to the heterojunction interface between the electron transit layer 24 and the electron supply layer 26 (e.g., within a range approximately a few nanometers from the interface). The 2DEG 28 in the electron transit layer 24 is used as a channel of the nitride semiconductor device 10. The sheet carrier density of the 2DEG 28, which is generated in the electron transit layer 24, will be increased when at least one of the Al composition and the thickness of the electron supply layer 26 is increased.

The nitride semiconductor layer 20 may further include a gate layer 30 formed above the electron supply layer 26. The gate layer 30 may be in contact with a portion of the electron supply layer 26. The gate layer 30 includes a bottom surface 30B in contact with the electron supply layer 26 and an upper surface 30A opposite to the bottom surface 30B.

The gate layer 30 is composed of a third nitride semiconductor containing an acceptor impurity. The third nitride semiconductor may include GaN. In the present embodiment, the third nitride semiconductor may include GaN as a main component. The acceptor impurity may include at least one of zinc (Zn), magnesium (Mg), and carbon (C). The maximum concentration of the acceptor impurity in the gate layer 30 may be in a range of 7×10¹⁸ cm⁻³ to 1×10²⁰ cm⁻³. The gate layer 30 may be a gallium nitride layer (p-type GaN layer) doped with an acceptor impurity.

The nitride semiconductor device 10 may further include the gate electrode 32. The gate electrode 32 may in contact with the upper surface 30A of the gate layer 30. The gate electrode 32 may be composed of one or more metal layers. In an example, the gate electrode 32 may be composed of titanium nitride (TiN). In another example, the gate electrode 32 may include a first metal layer composed of Ti and a second metal layer formed on the first metal layer and composed of TiN. The gate electrode 32 may form a Schottky junction with the gate layer 30. The gate electrode 32 may have a thickness that is, for example, in a range of 50 nm to 200 nm. The gate electrode 32 may be smaller in area in plan view than the upper surface 30A of the gate layer 30.

The nitride semiconductor device 10 may further include a passivation layer 34 that covers the electron supply layer 26, the gate layer 30, and the gate electrode 32. The passivation layer 34 includes a first opening 34A and a second opening 34B. The first opening 34A and the second opening 34B are separated from each other in the X-axis direction. The gate layer 30 is arranged between the first opening 34A and the second opening 34B. More specifically, the gate layer 30 may be arranged between the first opening 34A and the second opening 34B at a position closer to the first opening 34A than to the second opening 34B. The passivation layer 34 may be formed from, for example, at least one of silicon nitride (SiN), silicon dioxide (SiO₂), silicon oxynitride (SiON), aluminum oxide (Al₂O₃), AlN, and aluminum oxynitride (AlON). The passivation layer 34 may have a thickness, for example, in a range of 80 nm to 150 nm.

The nitride semiconductor device 10 further includes a source electrode 36, which is in contact with the electron supply layer 26 through the first opening 34A, and a drain electrode 38, which is in contact with the electron supply layer 26 through the second opening 34B. The source electrode 36 and the drain electrode 38 may be composed of one or more metal layers (e.g., any combination of a Ti layer, a TiN layer, an Al layer, an AlSiCu layer, an AlCu layer, and the like).

At least a portion of the source electrode 36 fills the first opening 34A. This allows the source electrode 36 to be in ohmic contact with the 2DEG 28, which is located immediately below the electron supply layer 26, through the first opening 34A. Similarly, at least a portion of the drain electrode 38 fills the second opening 34B. This allows the drain electrode 38 to be in ohmic contact with the 2DEG 28, which is located immediately below the electron supply layer 26, through the second opening 34B.

Thus, the nitride semiconductor device 10 includes at least one electrode (e.g., the gate electrode 32, the source electrode 36, and the drain electrode 38) formed above the nitride semiconductor layer 20.

### Field Plate Electrode

The nitride semiconductor device 10 may further optionally include a field plate electrode 40 formed on the passivation layer 34 and extending at least partially in a region between the gate layer 30 and the drain electrode 38 in plan view. In the example shown in FIG. 3, the field plate electrode 40 is formed integrally with the source electrode 36. Of the integrally formed electrode, the source electrode 36 may include at least the portion that is embedded in the first opening 34A of the passivation layer 34, and the field plate electrode 40 may include the remaining portion. It is sufficient that the field plate electrode 40 is electrically connected to the source electrode 36. The field plate electrode 40 does not necessarily have to be continuous with the source electrode 36.

The field plate electrode 40 is separated from the drain electrode 38. The field plate electrode 40 may include an end 40A located between the drain electrode 38 (second opening 34B) and the gate layer 30 in plan view.

When a drain voltage is applied to the drain electrode 38 in a zero bias state in which no gate voltage is applied to the gate electrode 32, the field plate electrode 40 reduces concentration of an electric field in the vicinity of an end of the gate electrode 32.

### Cross-Sectional Shape of Gate Layer

The gate layer 30 may include a ridge 42 that is in contact with the electron supply layer 26 and includes the upper surface 30A, and a first extension 44 and a second extension 46 that are in contact with the electron supply layer 26 and extend outward from the ridge 42 in plan view. Each of the first extension 44 and the second extension 46 has a smaller thickness than the ridge 42. In the present disclosure, the first extension 44 and the second extension 46 may be collectively referred to as “the extension.”

The first extension 44 extends from the ridge 42 toward the first opening 34A. The first extension 44 covers a portion of the surface of the electron supply layer 26 between the ridge 42 and the first opening 34A. The first extension 44 does not reach the source electrode 36, which fills the first opening 34A.

The second extension 46 extends from the ridge 42 toward the second opening 34B. The second extension 46 covers a portion of the surface of the electron supply layer 26 between the ridge 42 and the second opening 34B in plan view. The second extension 46 does not reach the drain electrode 38, which fills the second opening 34B.

The ridge 42 is arranged between the first extension 44 and the second extension 46 and formed integrally with the first extension 44 and the second extension 46. Since the gate layer 30 includes the first extension 44 and the second extension 46, the bottom surface 30B is greater in area than the upper surface 30A. In the example shown in FIG. 3, the second extension 46 may extend longer than the first extension 44 outward from the ridge 42 in plan view. In other words, the second extension 46 may be greater in dimension in the X-axis direction than the first extension 44. The dimension of the first extension 44 in the X-axis direction may be, for example, in a range of 0.2 μm to 0.3 μm. The dimension of the second extension 46 in the X-axis direction may be, for example, in a range of 0.2 μm to 0.6 μm.

The ridge 42 corresponds to a relatively thick portion of the gate layer 30. The ridge 42 may have a thickness that is, for example, in a range of 80 nm to 150 nm. In an example, the thickness of the ridge 42 may be greater than 110 nm. The first extension 44 and the second extension 46 have a smaller thickness than the ridge 42. In an example, the first extension 44 and the second extension 46 may be less than or equal to one-half of the thickness of the ridge 42.

Each of the first extension 44 and the second extension 46 may include a flat portion having a substantially constant thickness. The flat portion of each of the first extension 44 and the second extension 46 may have a thickness that is, for example in a range of 5 nm to 25 nm. In this specification, “substantially constant thickness” refers to a thickness being within a manufacturing variation range (for example, 20%). In addition, as shown in the drawing, each of the first extension 44 and the second extension 46 may include, between the flat portion and the ridge 42, an intermediate portion having a greater thickness than the flat portion. In an example, the intermediate portion has a thickness that gradually decreases as the ridge 42 becomes father away.

When the field plate electrode 40 is arranged, the end 40A of the field plate electrode 40 may be located between the second extension 46 and the drain electrode 38 in plan view.

### Planar Layout of Nitride Semiconductor Device

An example of a planar layout of the active region of the nitride semiconductor device 10 will now be described with reference to FIG. 2. In FIG. 2, the gate electrode 32, the source electrode 36, the drain electrode 38, and the field plate electrode 40 are indicated by broken lines. The first opening 34A and the second opening 34B of the passivation layer 34 are indicated by solid lines. The remaining portion of the passivation layer 34 is transparently shown. The first extension 44 and the second extension 46 are not shown in FIG. 2.

As shown in FIG. 2, the gate layer 30 may be formed to surround the drain electrode 38 in plan view. The gate layer 30 may include body portions 48 extending in the Y-axis direction and connection portions 50 connecting adjacent ones of the body portions 48. The body portion 48 of the gate layer 30 is arranged between the first opening 34A and the second opening 34B of the passivation layer 34.

In plan view, the gate electrode 32 is arranged to overlap the gate layer 30. Accordingly, in the same manner as the gate layer 30, the gate electrode 32 may be formed to surround the drain electrode 38 in plan view. The gate electrode 32 may include body portions 52 extending in the Y-axis direction and connection portions 54 connecting adjacent ones of the body portions 52.

The nitride semiconductor device 10 may include a gate interconnect 56, a source interconnect 58, and a drain interconnect 60. In FIG. 2, the gate interconnect 56, the source interconnect 58, and the drain interconnect 60 are indicated by single-dashed lines. The gate interconnect 56, the source interconnect 58, and the drain interconnect 60 are arranged above the source electrode 36 and the drain electrode 38 in the Z-axis direction. The gate interconnect 56 may extend in the X-axis direction and may be arranged above the connection portion 54 of the gate electrode 32. The source interconnect 58 and the drain interconnect 60 may extend in the X-axis direction and respectively intersect with the source electrode 36 and the drain electrode 38 in plan view. In an example, the gate electrode 32 may be electrically connected to the gate interconnect 56 through vias 62 arranged above the connection portion 54. The source electrode 36 may be electrically connected to the source interconnect 58 through vias 64. The drain electrode 38 may be electrically connected to the drain interconnect 60 through vias 66. The gate interconnect 56, the source interconnect 58, and the drain interconnect 60 may be electrically connected to the gate pad 12, the source pad 14, and the drain pad 16, respectively, shown in FIG. 1.

The planar layout of the active region of nitride semiconductor device 10 is not limited to the example shown in FIG. 2. Any alternative planar layout may be used.

### Detail of Buffer Layer

The buffer layer 22, which is included in the nitride semiconductor layer 20, will now be described in detail with reference to FIG. 4. FIG. 4 is a schematic diagram showing a stacking structure of a portion of the nitride semiconductor layer 20 formed above the semiconductor substrate 18.

As shown in FIG. 4, the buffer layer 22 may include a base buffer layer 68 in contact with the semiconductor substrate 18. In an example, the base buffer layer 68 may be composed of aluminum nitride (AlN). The base buffer layer 68 may have a thickness in a range of 100 nm to 300 nm.

The buffer layer 22 may further include a lower buffer layer 70, an intermediate buffer layer 72, and an upper buffer layer 74. In the present embodiment, the lower buffer layer 70 may be in contact with the base buffer layer 68.

The lower buffer layer 70 may have a first superlattice structure SL1 including first layers SL1A and second layers SL1B alternately arranged. The first layer SL1A is composed of AlₓGa₁₋ₓN, where 0<x<1. Preferably, x may satisfy 0.35<x<0.9. More preferably, x may satisfy 0.6<x<0.9. The second layer SL1B is composed of GaN. The first superlattice structure SL1 may include a two-layer structure that is formed of a first layer SL1A and a second layer SL1B and repeats between two times and five hundred times, inclusive, and preferably, between five times and one hundred times, inclusive. In the present embodiment, the lower buffer layer 70 includes the first superlattice structure SL1 and thus may be referred to as a first superlattice buffer layer. The lowermost one of the first layer SL1A in the first superlattice buffer layer (the lower buffer layer 70) may be in contact with the base buffer layer 68.

The first layer SL1A may have a thickness that is in a range of 5 nm to 7 nm. The second layer SL1B may have a thickness that is in a range of 2 nm to 3 nm. The first superlattice buffer layer (the lower buffer layer 70) may have a thickness that is greater than or equal to 100 nm. Preferably, the thickness of the first superlattice buffer layer (the lower buffer layer 70) may be in a range of 100 nm to 300 nm.

The first superlattice buffer layer (the lower buffer layer 70) may include at least one of iron (Fe), carbon (C), and silicon (Si) as an impurity. The concentration of the impurity of the first superlattice buffer layer (the lower buffer layer 70) may be, for example, greater than or equal to 4×10¹⁶ cm⁻³.

The intermediate buffer layer 72 may have a second superlattice structure SL2 including third layers SL2A and fourth layers SL2B alternately arranged. The third layer SL2A is composed of Al_{y}Ga_{1-y}N, where 0<y<x. Preferably, y may satisfy 0.1<y<0.65. More preferably, y may satisfy 0.35<y<0.65. The fourth layer SL2B is composed of GaN. The second superlattice structure SL2 may include a two-layer structure that is formed of a third layer SL2A and a fourth layer SL2B and repeats between two times and five hundred times, inclusive, and preferably, between five times and one hundred times, inclusive. In the present embodiment, the intermediate buffer layer 72 includes the second superlattice structure SL2 and thus may be referred to as a second superlattice buffer layer. The second superlattice buffer layer (the intermediate buffer layer 72) may be formed above the first superlattice buffer layer (the lower buffer layer 70). In the present embodiment, the second superlattice buffer layer (the intermediate buffer layer 72) may be in contact with the first superlattice buffer layer (the lower buffer layer 70). More specifically, the lowermost one of the third layers SL2A in the second superlattice buffer layer (the intermediate buffer layer 72) may be in contact with the uppermost one of the second layers SL1B in the first superlattice buffer layer (the lower buffer layer 70).

The third layer SL2A may have a thickness that is in a range of 5 nm to 7 nm. The fourth layer SL2B may have a thickness that is in a range of 2 nm to 3 nm. The second superlattice buffer layer (the intermediate buffer layer 72) may have a thickness that is greater than or equal to 100 nm. Preferably, the thickness of the second superlattice buffer layer (the intermediate buffer layer 72) may be in a range of 100 nm to 300 nm.

The second superlattice buffer layer (the intermediate buffer layer 72) may include at least one of iron (Fe), carbon (C), and silicon (Si) as an impurity. The concentration of the impurity of the second superlattice buffer layer (the intermediate buffer layer 72) may be, for example, greater than or equal to 4×10¹⁶ cm⁻³.

The upper buffer layer 74 may have a third superlattice structure SL3 including fifth layers SL3A and sixth layers SL3B alternately arranged. The fifth layer SL3A is composed of Al_{z}Ga_{1-z}N, where 0<z<y. Preferably, z may satisfy 0.1<z<0.4. The sixth layer SL3B is composed of GaN. The third superlattice structure SL3 may include a two-layer structure that is formed of a fifth layer SL3A and a sixth layer SL3B and repeats between two times and five hundred times, inclusive, and preferably, between five times and one hundred times, inclusive. In the present embodiment, the upper buffer layer 74 includes the third superlattice structure SL3 and thus may be referred to as a third superlattice buffer layer. The third superlattice buffer layer (the upper buffer layer 74) may be formed above the second superlattice buffer layer (the intermediate buffer layer 72). In the present embodiment, the third superlattice buffer layer (the upper buffer layer 74) may be in contact with the second superlattice buffer layer (the intermediate buffer layer 72). More specifically, the lowermost one of the fifth layers SL3A in the third superlattice buffer layer (the upper buffer layer 74) may be in contact with the uppermost one of the fourth layers SL2B in the second superlattice buffer layer (the intermediate buffer layer 72).

The fifth layer SL3A may have a thickness that is in a range of 5 nm to 7 nm. The sixth layer SL3B may have a thickness that is in a range of 2 nm to 3 nm. The third superlattice buffer layer (the upper buffer layer 74) may have a thickness that is greater than or equal to 100 nm. Preferably, the thickness of the third superlattice buffer layer (the upper buffer layer 74) may be in a range of 100 nm to 300 nm.

The electron transit layer 24 may be formed above the third superlattice buffer layer (the upper buffer layer 74). In the present embodiment, the electron transit layer 24 may be in contact with the third superlattice buffer layer (the upper buffer layer 74). More specifically, the electron transit layer 24 may be in contact with the uppermost one of the sixth layers SL3B in the third superlattice buffer layer (the upper buffer layer 74).

The third superlattice buffer layer (the upper buffer layer 74) may include at least one of iron (Fe), carbon (C), and silicon (Si) as an impurity. The concentration of the impurity of the third superlattice buffer layer (the upper buffer layer 74) may be, for example, greater than or equal to 4×10¹⁶ cm⁻³.

### Operation of Nitride Semiconductor Device

The operation of the nitride semiconductor device 10 will now be described. The nitride semiconductor device 10 includes the semiconductor substrate 18, the nitride semiconductor layer 20 formed above the semiconductor substrate 18, at least one electrode (e.g., the gate electrode 32, the source electrode 36, and the drain electrode 38) formed above the nitride semiconductor layer 20. The nitride semiconductor layer 20 includes the first superlattice buffer layer (the lower buffer layer 70), the second superlattice buffer layer (the intermediate buffer layer 72) formed above the first superlattice buffer layer, the electron transit layer 24 formed above the second superlattice buffer layer and composed of the first nitride semiconductor, and the electron supply layer 26 formed above the electron transit layer 24 and composed of the second nitride semiconductor having a larger bandgap than the first nitride semiconductor. The first superlattice buffer layer (the lower buffer layer 70) has the first superlattice structure SL1 including first layers SL1A and second layers SL1B alternately arranged. The first layer SL1A is composed of AlₓGa₁₋ₓN, where 0<x<1. The second layer SL1B is composed of GaN. The second superlattice buffer layer (the intermediate buffer layer 72) has the second superlattice structure SL2 including third layers SL2A and fourth layers SL2B alternately arranged. The third layer SL2A is composed of Al_{y}Ga_{1-y}N, where 0<y<x. The fourth layer SL2B is composed of GaN.

In the nitride semiconductor device 10 of the present embodiment, the nitride semiconductor layer 20 includes the first superlattice buffer layer and the second superlattice buffer layer formed above the first superlattice buffer layer. This decreases the stress in the nitride semiconductor device 10 while reducing the number of dislocation lines that reach the electron transit layer 24 or the electron supply layer 26. As a result, the breakdown voltage and the reliability of the nitride semiconductor device 10 are increased.

A mismatch of the lattice constants of the semiconductor substrate 18 and the nitride semiconductor layer 20 may produce dislocation lines in the nitride semiconductor layer 20. In the nitride semiconductor device 10, the semiconductor substrate 18 and the source electrode 36 may have the same potential. Thus, dislocation lines that extend in a direction intersecting the surface of the semiconductor substrate 18 may decrease the vertical breakdown voltage of the nitride semiconductor device 10. When the dislocation lines are present in a relatively upper portion (e.g., the electron transit layer 24, the electron supply layer 26, or the gate layer 30) of the nitride semiconductor layer 20, leakage current may be increased, and the reliability may deteriorate due to electric field concentration.

In this regard, in the nitride semiconductor device 10 of the present embodiment, the first superlattice structure SL1 and the second superlattice structure SL2 include a plurality of interfaces, which reduce the number of dislocation lines reaching a relatively upper portion of the nitride semiconductor layer 20.

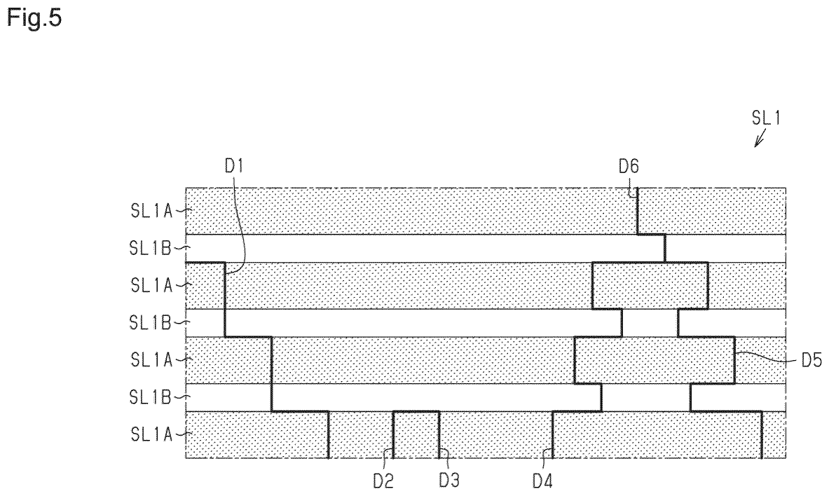

FIG. 5 is a schematic diagram showing a mechanism of eliminating dislocation lines using a superlattice structure. FIG. 5 is a diagram showing an example of dislocation lines D1 to D6 formed in a portion of the first superlattice buffer layer having the first superlattice structure SL1. In the first superlattice structure SL1, the first layers SL1A and the second layers SL1B are alternately arranged and thus have multiple interfaces, which cause the dislocation lines D1 to D6 to bend. The dislocation line D1, which bends in interfaces between the first layer SL1A and the second layer SL1B, may be inclined from the stacking direction (i.e., the Z-axis direction shown in FIG. 3, corresponding to the growth direction of the nitride semiconductor layer 20) of the superlattice structure. The dislocation lines D2 and D3, which bend in an interface between the first layer SL1A and the second layer SL1B, may intercept each other. As a result, the dislocation lines D2 and D3 may be eliminated in a location above the location where the dislocation lines D2 and D3 intercept each other. The dislocation lines D4 and D5, which bend in interfaces between the first layer SL1A and the second layer SL1B, may intercept each other. As a result, the dislocation lines D4 and D5 may become the single dislocation line D6 in a location above the location where the dislocation lines D4 and D5 intercept each other. As described above, the superlattice structure in which the two-layer structure of AlGaN/GaN repeats (e.g., the first superlattice structure SL1, the second superlattice structure SL2, and the third superlattice structure SL3) includes multiple interfaces. Thus, the density of dislocation lines is reduced in layers located at a higher position.

The nitride semiconductor layer 20 of the present embodiment may include multiple dislocation lines (for example, dislocation lines D1 to D6 shown in FIG. 5). However, with the dislocation line elimination mechanism described above, in a region below at least one of the electrodes, the number of dislocation lines extending in the interface between the electron transit layer 24 and the electron supply layer 26 is less than the number of dislocation lines extending from the bottom surface 20B of the nitride semiconductor layer 20.

In addition, in the present embodiment, AlGaN contained in the first superlattice buffer layer has a greater Al composition than AlGaN contained in the second superlattice buffer layer. Thus, the first superlattice buffer layer has a greater strain in the two-layer structure of AlGaN/GaN than the second superlattice buffer layer. In the nitride semiconductor layer 20, the number of dislocation lines is relatively large near the semiconductor substrate 18 (near interface between different types of materials). In this regard, the first superlattice buffer layer, which includes AlGaN having a relatively great Al composition, is arranged near the semiconductor substrate 18. Thus, the dislocation lines are effectively eliminated. The second superlattice buffer layer, which includes AlGaN having a relatively small Al composition, is arranged near the electron transit layer 24. Thus, the stress in the nitride semiconductor device 10 is reduced effectively.

In the present embodiment, the nitride semiconductor layer 20 further includes the third superlattice buffer layer (the upper buffer layer 74) formed above the second superlattice buffer layer (the intermediate buffer layer 72). The third superlattice buffer layer (the upper buffer layer 74) has the third superlattice structure SL3 including fifth layers SL3A and sixth layers SL3B alternately arranged. The fifth layer SL3A is composed of Al_{z}Ga_{1-z}N, where 0<z<y. The sixth layer SL3B is composed of GaN. The electron transit layer 24 may be formed above the third superlattice buffer layer (the upper buffer layer 74).

In the present embodiment, the first superlattice buffer layer, which includes AlGaN having a relatively great Al composition, is arranged near the semiconductor substrate 18. The third superlattice buffer layer, which includes AlGaN having a relatively small Al composition, is arranged near the electron transit layer 24. Thus, in the nitride semiconductor device 10 of the present embodiment, the elimination of dislocation lines and the reduction of stress are achieved more effectively. As a result, the breakdown voltage and the reliability of the nitride semiconductor device 10 are increased.

The nitride semiconductor device 10 of the present embodiment has the following advantages.

(1-1) The nitride semiconductor layer 20 includes the first superlattice buffer layer (the lower buffer layer 70), the second superlattice buffer layer (the intermediate buffer layer 72) formed above the first superlattice buffer layer, the electron transit layer 24 formed above the second superlattice buffer layer (the intermediate buffer layer 72) and composed of the first nitride semiconductor, and the electron supply layer 26 formed above the electron transit layer 24 and composed of the second nitride semiconductor having a larger bandgap than the first nitride semiconductor. The first superlattice buffer layer (the lower buffer layer 70) has the first superlattice structure SL1 including first layers SL1A and second layers SL1B alternately arranged. The first layer SL1A is composed of AlₓGa₁₋ₓN, where 0<x<1. The second layer SL1B is composed of GaN. The second superlattice buffer layer (the intermediate buffer layer 72) has the second superlattice structure SL2 including third layers SL2A and fourth layers SL2B alternately arranged. The third layer SL2A is composed of Al_{y}Ga_{1-y}N, where 0<y<x. The fourth layer SL2B is composed of GaN.

This configuration reduces the stress in the nitride semiconductor device 10 while reducing the number of dislocation lines reaching the electron transit layer 24 or the electron supply layer 26. Thus, the breakdown voltage and the reliability of the nitride semiconductor device 10 are increased.

(1-2) The nitride semiconductor layer 20 may further include the third superlattice buffer layer (the upper buffer layer 74) formed above the second superlattice buffer layer (the intermediate buffer layer 72). The third superlattice buffer layer (the upper buffer layer 74) has the third superlattice structure SL3 including fifth layers SL3A and sixth layers SL3B alternately arranged. The fifth layer SL3A is composed of Al_{z}Ga_{1-z}N, where 0<z<y. The sixth layer SL3B is composed of GaN. The electron transit layer 24 may be formed above the third superlattice buffer layer (the upper buffer layer 74).

With this configuration, the first superlattice buffer layer, which includes AlGaN having a relatively great Al composition, is arranged near the semiconductor substrate 18. The third superlattice buffer layer, which includes AlGaN having a relatively small Al composition, is arranged near the electron transit layer 24. Thus, the elimination of dislocation lines and the reduction of stress are achieved more effectively.

(1-3) The nitride semiconductor layer 20 may further include the base buffer layer 68 in contact with the semiconductor substrate 18. The base buffer layer 68 may be composed of AlN.

This configuration limits strain of the lattice in the vicinity of the interface between the semiconductor substrate 18 and the nitride semiconductor layer 20.

(1-4) In a region below at least one of the electrodes, the number of dislocation lines extending in the interface between the electron transit layer 24 and the electron supply layer 26 may be less than the number of dislocation lines extending from the bottom surface 20B of the nitride semiconductor layer 20.

In this structure, the number of dislocation lines is reduced in a position relatively near the electrodes. Thus, the reliability of the nitride semiconductor device 10 is increased.

(1-5) The first superlattice structure SL1 may include a two-layer structure that is formed of the first layer SL1A and the second layer SL1B and repeats between two times and five hundred times, inclusive.

With this configuration, multiple interfaces are formed in the first superlattice structure SL1. Thus, the number of dislocation lines in the nitride semiconductor layer 20 is reduced.

(1-6) The second superlattice structure SL2 may include a two-layer structure that is formed of the third layer SL2A and the fourth layer SL2B and repeats between two times and five hundred times, inclusive.

With this configuration, multiple interfaces are formed in the second superlattice structure SL2. Thus, the number of dislocation lines in the nitride semiconductor layer 20 is reduced.

(1-7) The third superlattice structure SL3 may include a two-layer structure that is formed of the fifth layer SL3A and the sixth layer SL3B and repeats between two times and five hundred times, inclusive.

With this configuration, multiple interfaces are formed in the third superlattice structure SL3. Thus, the number of dislocation lines in the nitride semiconductor layer 20 is reduced.

(1-8) The off-angle of the semiconductor substrate 18 may be greater than 0° and less than or equal to 1°. When the semiconductor substrate 18 has an off-angle, a defect caused by polarity inversion is less likely to occur in the nitride semiconductor layer 20. When the off-angle is less than or equal to 1°, non-uniformity of the thickness of the nitride semiconductor layer 20 and increase in the surface roughness of the nitride semiconductor layer 20 are limited.

(1-9) The thickness of the electron transit layer 24 may be less than or equal to 760 nm. In the nitride semiconductor device 10, the dislocation density is reduced even when the electron transit layer 24 has a relatively small thickness.

(1-10) The nitride semiconductor layer 20 may further include a gate layer 30 formed above the electron supply layer 26. The gate layer 30 may be composed of a third nitride semiconductor containing an acceptor impurity. This configuration achieves the normally-off operation of the nitride semiconductor device 10.

(1-11) The first superlattice buffer layer (the lower buffer layer 70) may include at least one of Fe, C, and Si as an impurity. This configuration inhibits current leakage in the first superlattice buffer layer (the lower buffer layer 70).

(1-12) The second superlattice buffer layer (the intermediate buffer layer 72) may include at least one of Fe, C, and Si as an impurity. This configuration inhibits current leakage in the second superlattice buffer layer (the intermediate buffer layer 72).

(1-13) The third superlattice buffer layer (the upper buffer layer 74) may include at least one of Fe, C, and Si as an impurity. This configuration inhibits current leakage in the third superlattice buffer layer (the upper buffer layer 74).

(1-14) The gate layer 30 may include the ridge 42 in contact with the electron supply layer 26 and including the upper surface 30A of the gate layer 30, and the extensions 44 and 46 in contact with the electron supply layer 26 and extending outward from the ridge 42 in plan view. Each of the extensions 44 and 46 has a smaller thickness than the ridge 42. Since the gate layer 30 includes the extensions 44 and 46 having a smaller thickness than the ridge 42, local concentration of electric field in the gate layer 30 is limited. This improves the gate reliability of the nitride semiconductor device 10.

(1-15) In the nitride semiconductor layer 20, x may satisfy 0.35<x<0.9, and y may satisfy 0.1<y<0.65. When the Al composition of AlGaN in the nitride semiconductor layer 20 is changed in a stepped manner, the elimination of dislocation lines and the reduction of stress are achieved more effectively in the nitride semiconductor device 10.

### MODIFIED EXAMPLE OF FIRST EMBODIMENT

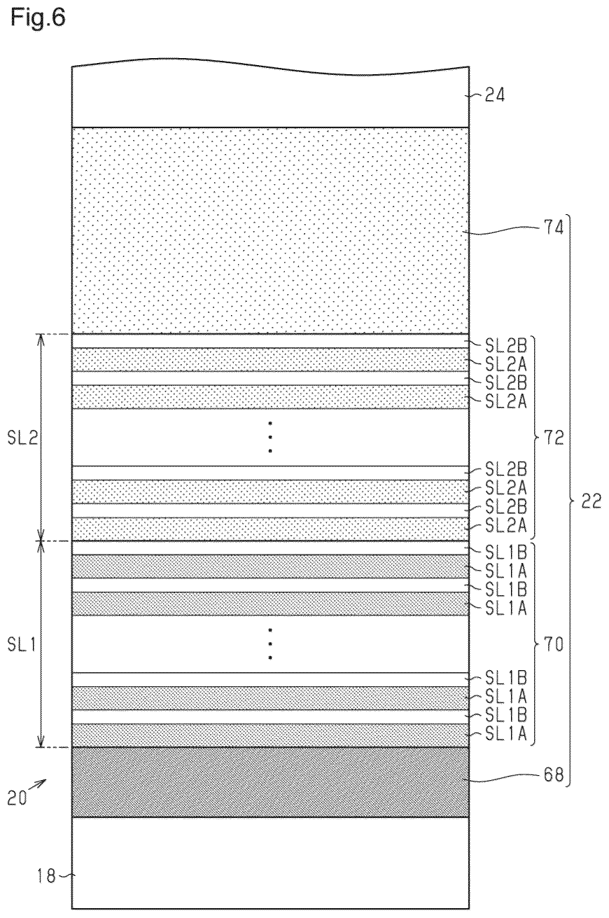

Modified examples of the nitride semiconductor device 10 according to the first embodiment will now be described with reference to FIGS. 6 to 8. In the modified examples described below, the superlattice structure may be omitted from one of the lower buffer layer 70, the intermediate buffer layer 72, and the upper buffer layer 74.

### First Modified Example

FIG. 6 is a schematic diagram showing a stacking structure of a portion of the nitride semiconductor layer 20 formed above the semiconductor substrate 18 in a first modified example. In the first modified example, the nitride semiconductor layer 20 may include the lower buffer layer 70 (the first superlattice buffer layer) having the first superlattice structure SL1, the intermediate buffer layer 72 (the second superlattice buffer layer) having the second superlattice structure SL2, and an upper buffer layer 74 that does not have a superlattice structure.

The first superlattice structure SL1 of the lower buffer layer 70 has first layers SL1A and second layers SL1B alternately arranged. The first layer SL1A is composed of AlₓGa₁₋ₓN, where 0<x<1. In the first modified example, preferably, x may satisfy 0.35<x<0.9. More preferably, x may satisfy 0.6<x<0.9. The second layer SL1B is composed of GaN. The second superlattice structure SL2 of the intermediate buffer layer 72 has third layers SL2A and fourth layers SL2B alternately arranged. The third layer SL2A is composed of Al_{y}Ga_{1-y}N, where 0<y<x. In the first modified example, preferably, y may satisfy 0.1<y<0.65. More preferably, y may satisfy 0.35<y<0.65. The fourth layer SL2B is composed of GaN. In the first modified example, the remaining configurations of the first superlattice structure SL1 and the second superlattice structure SL2 may be the same as those in the first embodiment.

The upper buffer layer 74 is composed of AlᵤGa₁₋ᵤN, where 0<u<y. Preferably, u may satisfy 0.1<u<0.4. The upper buffer layer 74 is arranged between the second superlattice buffer layer (the intermediate buffer layer 72) and the electron transit layer 24.

As described above, in the first modified example, buffer layers located at higher positions have smaller Al compositions. Thus, the stress in the nitride semiconductor device 10 is reduced effectively. The nitride semiconductor layer 20 includes the first superlattice buffer layer and the second superlattice buffer layer. Thus, the number of dislocation lines reaching the electron transit layer 24 or the electron supply layer 26 is reduced. As a result, the breakdown voltage and the reliability of the nitride semiconductor device 10 are increased.

### Second Modified Example

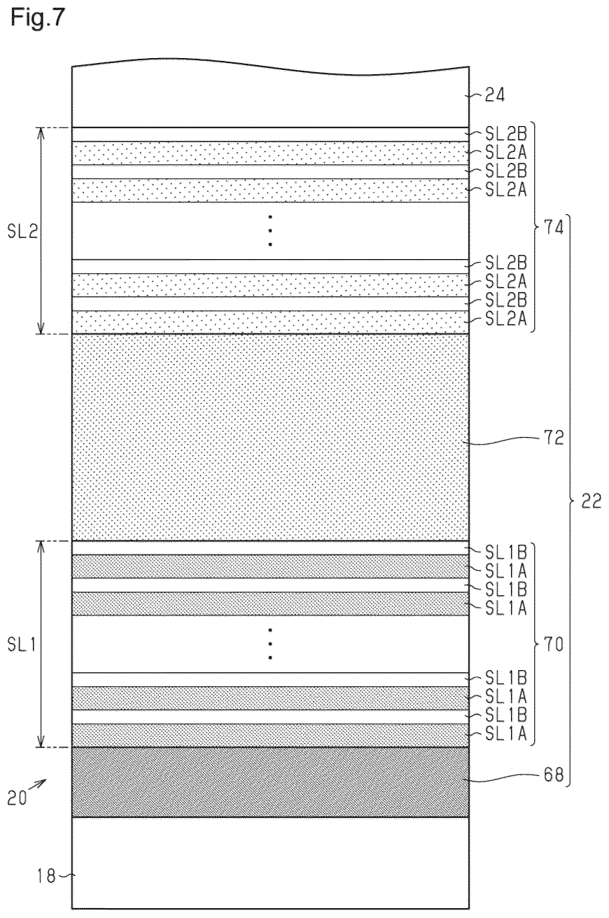

FIG. 7 is a schematic diagram showing a stacking structure of a portion of the nitride semiconductor layer 20 formed above the semiconductor substrate 18 in a second modified example. In the second modified example, the nitride semiconductor layer 20 may include the lower buffer layer 70 (the first superlattice buffer layer) having the first superlattice structure SL1, an intermediate buffer layer 72 that does not have a superlattice structure, and the upper buffer layer 74 (the second superlattice buffer layer) having the second superlattice structure SL2.

The first superlattice structure SL1 of the lower buffer layer 70 has first layers SL1A and second layers SL1B alternately arranged. The first layer SL1A is composed of AlₓGa₁₋ₓN, where 0<x<1. In the second modified example, preferably, x may satisfy 0.35<x<0.9. More preferably, x may satisfy 0.6<x<0.9. The second layer SL1B is composed of GaN. The second superlattice structure SL2 of the upper buffer layer 74 has third layers SL2A and fourth layers SL2B alternately arranged. The third layer SL2A is composed of Al_{y}Ga_{1-y}N, where 0<y<x. In the second modified example, preferably, y may satisfy 0.1<y<0.65. More preferably, y may satisfy 0.1<y<0.4. The fourth layer SL2B is composed of GaN. In the second modified example, the remaining configurations of the first superlattice structure SL1 and the second superlattice structure SL2 may be the same as those in the first embodiment.

The intermediate buffer layer 72 is composed of AlᵢGa₁₋ᵢN, where y<i<x. Preferably, i may satisfy 0.35<i<0.65. The intermediate buffer layer 72 is arranged between the first superlattice buffer layer (the lower buffer layer 70) and the second superlattice buffer layer (the upper buffer layer 74).

As described above, in the second modified example, buffer layers located at higher positions have smaller Al compositions. Thus, the stress in the nitride semiconductor device 10 is reduced effectively. The nitride semiconductor layer 20 includes the first superlattice buffer layer and the second superlattice buffer layer. Thus, the number of dislocation lines reaching the electron transit layer 24 or the electron supply layer 26 is reduced. As a result, the breakdown voltage and the reliability of the nitride semiconductor device 10 are increased.

### Third Modified Example

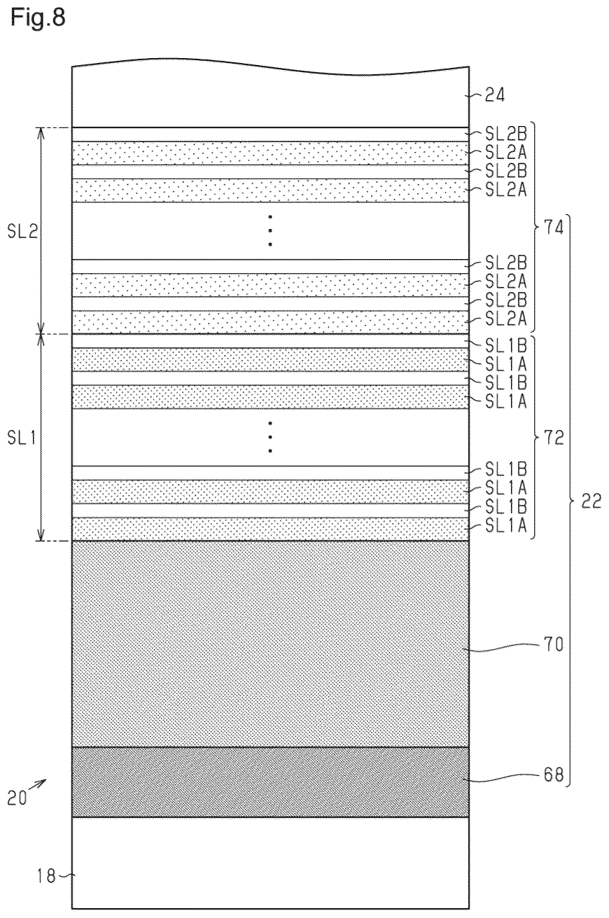

FIG. 8 is a schematic diagram showing a stacking structure of a portion of the nitride semiconductor layer 20 formed above the semiconductor substrate 18 in a third modified example. In the third modified example, the nitride semiconductor layer 20 may include a lower buffer layer 70 that does not have a superlattice structure, the intermediate buffer layer 72 (the first superlattice buffer layer) having the first superlattice structure SL1, and the upper buffer layer 74 (the second superlattice buffer layer) having the second superlattice structure SL2.

The first superlattice structure SL1 of the intermediate buffer layer 72 has first layers SL1A and second layers SL1B alternately arranged. The first layer SL1A is composed of AlₓGa₁₋ₓN, where 0<x<1. In the third modified example, preferably, x may satisfy 0.35<x<0.9. More preferably, x may satisfy 0.35<x<0.65. The second layer SL1B is composed of GaN. The second superlattice structure SL2 of the upper buffer layer 74 has third layers SL2A and fourth layers SL2B alternately arranged. The third layer SL2A is composed of Al_{y}Ga_{1-y}N, where 0<y<x. In the third modified example, preferably, y may satisfy 0.1<y<0.65. More preferably, y may satisfy 0.1<y<0.4. The fourth layer SL2B is composed of GaN. In the third modified example, the remaining configurations of the first superlattice structure SL1 and the second superlattice structure SL2 may be the same as those in the first embodiment.

The lower buffer layer 70 is composed of Al_{b}Ga_{1-b}N, where x<b<1. Preferably, b may satisfy 0.6<b<0.9. The lower buffer layer 70 is arranged between the semiconductor substrate 18 and the first superlattice buffer layer (the intermediate buffer layer 72).

As described above, in the third modified example, buffer layers located at higher positions have smaller Al compositions. Thus, the stress in the nitride semiconductor device 10 is reduced effectively. The nitride semiconductor layer 20 includes the first superlattice buffer layer and the second superlattice buffer layer. Thus, the number of dislocation lines reaching the electron transit layer 24 or the electron supply layer 26 is reduced. As a result, the breakdown voltage and the reliability of the nitride semiconductor device 10 are increased.

### Second Embodiment

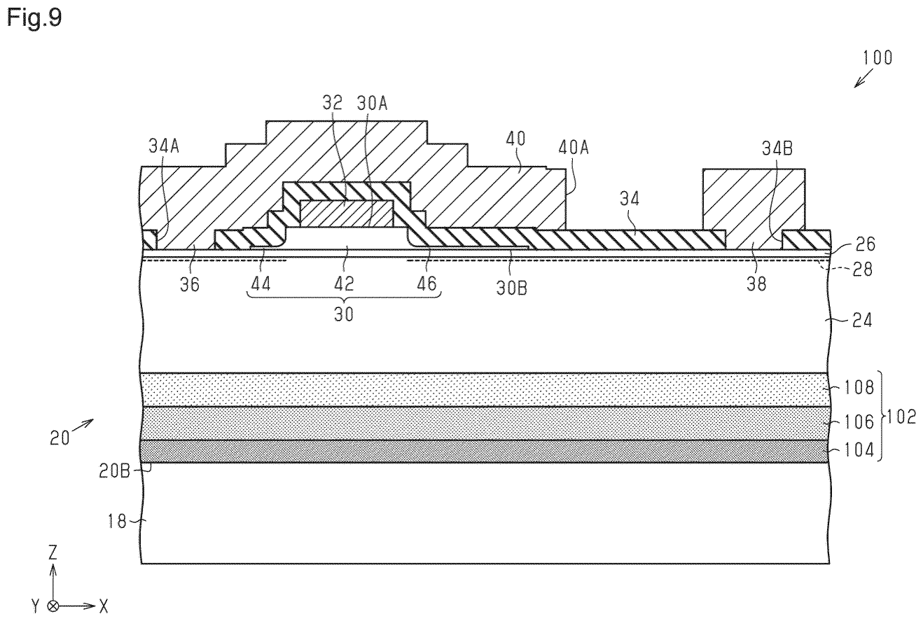

FIG. 9 is a schematic cross-sectional view of a nitride semiconductor device 100 in a second embodiment. As shown in FIG. 9, in the nitride semiconductor device 100, the nitride semiconductor layer 20 includes a buffer layer 102 instead of the buffer layer 22 (refer to FIG. 3) of the first embodiment. The remaining configuration of the nitride semiconductor device 100 may be the same as that of the nitride semiconductor device 10 of the first embodiment.

The buffer layer 102 may include a base buffer layer 104 that is in contact with the semiconductor substrate 18. In an example, the base buffer layer 104 may be composed of aluminum nitride (AlN). The base buffer layer 104 may have a thickness in a range of 100 nm to 300 nm.

The buffer layer 102 may further include a first superlattice buffer layer 106 and a second superlattice buffer layer 108. In the present embodiment, the first superlattice buffer layer 106 may be in contact with the base buffer layer 104. The second superlattice buffer layer 108 may be in contact with the electron transit layer 24.

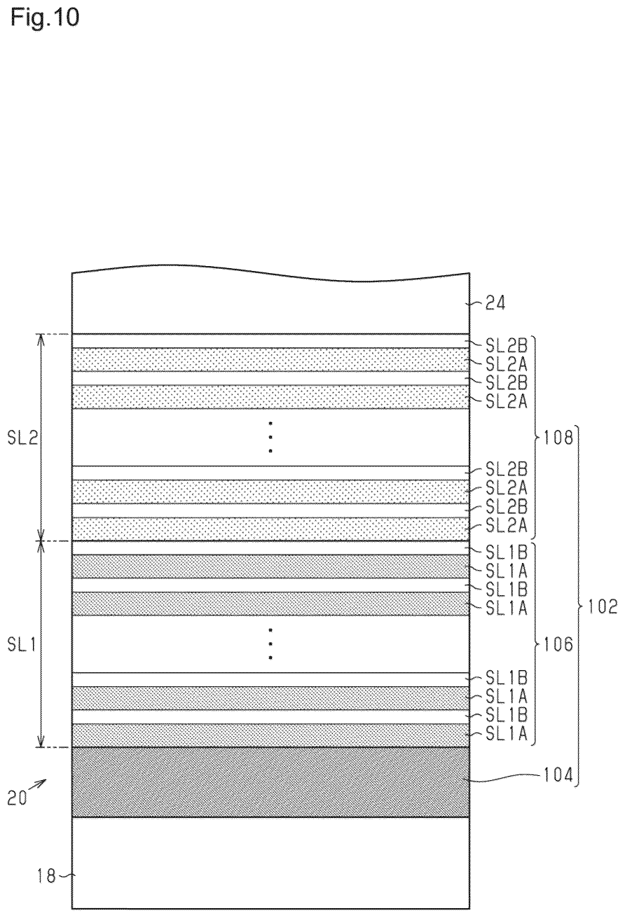

FIG. 10 is a schematic diagram showing a stacking structure of a portion of the nitride semiconductor layer 20 formed above the semiconductor substrate 18. As shown in FIG. 10, the first superlattice buffer layer 106 may have the first superlattice structure SL1 including first layers SL1A and second layers SL1B alternately arranged. The first layer SL1A is composed of AlₓGa₁₋ₓN, where 0<x<1. Preferably, x may satisfy 0.35<x<0.9. The second layer SL1B is composed of GaN. The first superlattice structure SL1 may include a two-layer structure that is formed of a first layer SL1A and a second layer SL1B and repeats between two times and five hundred times, inclusive, and preferably, between five times and one hundred times, inclusive. The lowermost one of the first layers SL1A in the first superlattice buffer layer 106 may be in contact with the base buffer layer 104.

The first layer SL1A may have a thickness that is in a range of 5 nm to 7 nm. The second layer SL1B may have a thickness that is in a range of 2 nm to 3 nm. The first superlattice buffer layer 106 may have a thickness that is greater than or equal to 100 nm. Preferably, the thickness of the first superlattice buffer layer 106 may be in a range of 100 nm to 300 nm.

The first superlattice buffer layer 106 may include at least one of iron (Fe), carbon (C), and silicon (Si) as an impurity. The concentration of the impurity of the first superlattice buffer layer 106 may be, for example, greater than or equal to 4×10¹⁶ cm⁻³.

The second superlattice buffer layer 108 may have the second superlattice structure SL2 including third layers SL2A and fourth layers SL2B alternately arranged. The third layer SL2A is composed of Al_{y}Ga_{1-y}N, where 0<y<x. Preferably, y may satisfy 0.1<y<0.65. The fourth layer SL2B is composed of GaN. The second superlattice structure SL2 may include a two-layer structure that is formed of a third layer SL2A and a fourth layer SL2B and repeats between two times and five hundred times, inclusive, and preferably, between five times and one hundred times, inclusive. The second superlattice buffer layer 108 is formed above the first superlattice buffer layer 106. In the present embodiment, the second superlattice buffer layer 108 may be in contact with the first superlattice buffer layer 106. More specifically, the lowermost one of the third layers SL2A in the second superlattice buffer layer 108 may be in contact with the uppermost one of the second layers SL1B in the first superlattice buffer layer 106.

The third layer SL2A may have a thickness that is in a range of 5 nm to 7 nm. The fourth layer SL2B may have a thickness that is in a range of 2 nm to 3 nm. The second superlattice buffer layer 108 may have a thickness that is greater than or equal to 100 nm. Preferably, the thickness of the second superlattice buffer layer 108 may be in a range of 100 nm to 300 nm.

The second superlattice buffer layer 108 may include at least one of iron (Fe), carbon (C), and silicon (Si) as an impurity. The concentration of the impurity of the second superlattice buffer layer 108 may be, for example, greater than or equal to 4×10¹⁶ cm⁻³.

As described above, in the second embodiment, buffer layers located at higher positions (i.e., the second superlattice buffer layer 108) have smaller Al compositions. Thus, the stress in the nitride semiconductor device 100 is reduced effectively. The nitride semiconductor layer 20 includes the first superlattice buffer layer 106 and the second superlattice buffer layer 108. Thus, the number of dislocation lines reaching the electron transit layer 24 or the electron supply layer 26 is reduced. As a result, the breakdown voltage and the reliability of the nitride semiconductor device 100 are increased.

The nitride semiconductor device 100 of the present embodiment has the following advantages.

(2-1) The nitride semiconductor layer 20 includes the first superlattice buffer layer 106, the second superlattice buffer layer 108 formed above the first superlattice buffer layer 106, the electron transit layer 24 formed above the second superlattice buffer layer 108 and composed of the first nitride semiconductor, and the electron supply layer 26 formed above the electron transit layer 24 and composed of the second nitride semiconductor having a larger bandgap than the first nitride semiconductor. The first superlattice buffer layer 106 may have the first superlattice structure SL1 including first layers SL1A and second layers SL1B alternately arranged. The first layer SL1A is composed of AlₓGa₁₋ₓN, where 0<x<1. The second layer SL1B is composed of GaN. The second superlattice buffer layer 108 has the second superlattice structure SL2 including third layers SL2A and fourth layers SL2B alternately arranged. The third layer SL2A is composed of Al_{y}Ga_{1-y}N, where 0<y<x. The fourth layer SL2B is composed of GaN.

This configuration reduces the stress in the nitride semiconductor device 100 while reducing the number of dislocation lines reaching the electron transit layer 24 or the electron supply layer 26. Thus, the breakdown voltage and the reliability of the nitride semiconductor device 100 are increased.

(2-2) The nitride semiconductor layer 20 may further include the base buffer layer 104 in contact with the semiconductor substrate 18. The base buffer layer 104 may be composed of AlN.

This configuration limits strain of the lattice in the vicinity of the interface between the semiconductor substrate 18 and the nitride semiconductor layer 20.

(2-3) In a region below at least one of the electrodes, the number of dislocation lines extending in the interface between the electron transit layer 24 and the electron supply layer 26 may be less than the number of dislocation lines extending from the bottom surface 20B of the nitride semiconductor layer 20.

In this structure, the number of dislocation lines is reduced in a position relatively near the electrodes. This increases the reliability of the nitride semiconductor device 100.

(2-4) The first superlattice structure SL1 may include a two-layer structure that is formed of the first layer SL1A and the second layer SL1B and repeats between two times and five hundred times, inclusive.

With this configuration, multiple interfaces are formed in the first superlattice structure SL1. Thus, the number of dislocation lines in the nitride semiconductor layer 20 is reduced.

(2-5) The second superlattice structure SL2 may include a two-layer structure that is formed of the third layer SL2A and the fourth layer SL2B and repeats between two times and five hundred times, inclusive.

With this configuration, multiple interfaces are formed in the second superlattice structure SL2. Thus, the number of dislocation lines in the nitride semiconductor layer 20 is reduced.

(2-6) The off-angle of the semiconductor substrate 18 may be greater than 0° and less than or equal to 1°. When the semiconductor substrate 18 has an off-angle, a defect caused by polarity inversion is less likely to occur in the nitride semiconductor layer 20. When the off-angle is less than or equal to 1°, non-uniformity of the thickness of the nitride semiconductor layer 20 and increase in the surface roughness of the nitride semiconductor layer 20 are limited.

(2-7) The thickness of the electron transit layer 24 may be less than or equal to 760 nm. In the nitride semiconductor device 100, the dislocation density is reduced even when the electron transit layer 24 has a relatively small thickness.

(2-8) The nitride semiconductor layer 20 may further include a gate layer 30 formed above the electron supply layer 26. The gate layer 30 may be composed of a third nitride semiconductor containing an acceptor impurity. This configuration achieves the normally-off operation of the nitride semiconductor device 100.

(2-9) The first superlattice buffer layer 106 may include at least one of Fe, C, and Si as an impurity. This configuration inhibits current leakage in the first superlattice buffer layer 106.

(2-10) The second superlattice buffer layer 108 may include at least one of Fe, C, and Si as an impurity. This configuration inhibits current leakage in the second superlattice buffer layer 108.

(2-11) The gate layer 30 may include the ridge 42 in contact with the electron supply layer 26 and including the upper surface 30A of the gate layer 30, and the extensions 44 and 46 in contact with the electron supply layer 26 and extending outward from the ridge 42 in plan view. Each of the extensions 44 and 46 has a smaller thickness than the ridge 42. Since the gate layer 30 includes the extensions 44 and 46 having a smaller thickness than the ridge 42, local concentration of electric field in the gate layer 30 is limited. This improves the gate reliability of the nitride semiconductor device 100.

(2-12) In the nitride semiconductor layer 20, x may satisfy 0.35<x<0.9, and y may satisfy 0.1<y<0.65. When the Al composition of AlGaN in the nitride semiconductor layer 20 is changed in a stepped manner, the elimination of dislocation lines and the reduction of stress are achieved more effectively in the nitride semiconductor device 100.

### Other Modified Examples

The embodiments and the modified examples described above may be modified as follows.

The buffer layer 22 shown in FIG. 3 includes the base buffer layer 68, the lower buffer layer 70, the intermediate buffer layer 72, and the upper buffer layer 74. However, the buffer layer 22 may further include an additional buffer layer (not shown). The additional buffer layer may be composed of the same material as the material of one of the base buffer layer 68, the lower buffer layer 70, and the intermediate buffer layer 72, and the upper buffer layer 74 or may be composed of a different material. For example, the additional buffer layer may include a single AlN layer, a single AlGaN layer, a layer having a superlattice structure of AlGaN/GaN, a layer having a superlattice structure of AlN/AlGaN, or a layer having a superlattice structure of AlN/GaN.

The base buffer layer 68 may be omitted from the buffer layer 22. In this case, for example, the lower buffer layer 70, corresponding to the first superlattice buffer layer, may be in contact with the semiconductor substrate 18.

The first superlattice buffer layer may have a greater thickness than the second superlattice buffer layer. By further increasing the thickness of the first superlattice buffer layer, which is located near the semiconductor substrate 18 and includes AlGaN having a relatively large Al composition, the number of dislocation lines in the nitride semiconductor layer 20 is further reduced. The increasing of the thickness of the first superlattice buffer layer may refer to increasing of the number of times of repeating the two-layer structure of AlGaN/GaN in the first superlattice structure SL1.

The nitride semiconductor device 10 may form a normally-on HEMT. In this case, the gate layer 30 may be omitted from the nitride semiconductor layer 20.

One or more of the various examples described in this specification may be combined within a range where there is no technical inconsistency.

In this specification, “at least one of A and B” should be understood to mean “only A, or only B, or both A and B.”

The directional terms used in this specification such as “vertical,” “horizontal,” “above,” “below,” “top,” “bottom,” “frontward,” “backward,” “longitudinal,” “lateral,” “left,” “right,” “front,” and “back” will depend upon a particular orientation of the device being described and illustrated. The present disclosure may include various alternative orientations. Therefore, the directional terms should not be narrowly construed.

For example, the Z-axis direction as referred to in this specification does not necessarily have to be the vertical direction and does not necessarily have to fully conform to the vertical direction. For example, the X-axis direction may conform to the vertical direction. The Y-axis direction may conform to the vertical direction.

### Clauses

The technical aspects that are understood from the present disclosure will hereafter be described. It should be noted that, for the purpose of facilitating understanding with no intention to limit, elements described in clauses are given the reference characters of the corresponding elements of the embodiments. The reference signs are used as examples to facilitate understanding, and the elements in each clause are not limited to those elements given with the reference signs.

[Clause 1] A nitride semiconductor device, including:
a semiconductor substrate (18);
a nitride semiconductor layer (20) formed above the semiconductor substrate (18); and
at least one electrode (32, 36, 38) formed above the nitride semiconductor layer (20), where
the nitride semiconductor layer (20) includes
   a first superlattice buffer layer (70; 72; 106),
   a second superlattice buffer layer (72; 74; 108) formed above the first superlattice buffer layer (70; 72; 106),
   an electron transit layer (24) formed above the second superlattice buffer layer (72; 74; 108) and composed of a first nitride semiconductor, and
   an electron supply layer (26) formed above the electron transit layer (24) and composed of a second nitride semiconductor having a larger bandgap than the first nitride semiconductor,
the first superlattice buffer layer (70; 72; 106) has a first superlattice structure (SL1) including a first layer (SL1A) and a second layer (SL1B) that are alternately arranged,
the first layer (SL1A) is composed of AlₓGa₁₋ₓN, where 0<x<1,
the second layer (SL1B) is composed of GaN,
the second superlattice buffer layer (72; 74; 108) has a second superlattice structure (SL2) including a third layer (SL2A) and a fourth layer (SL2B) that are alternately arranged,
the third layer (SL2A) is composed of Al_{y}Ga_{1-y}N, where 0<y<x, and
the fourth layer (SL2B) is composed of GaN.

[Clause 2, FIG. 4] The nitride semiconductor device according to clause 1, where
the nitride semiconductor layer (20) further includes a third superlattice buffer layer (74) formed above the second superlattice buffer layer (72),
the third superlattice buffer layer (74) has a third superlattice structure (SL3) including a fifth layer (SL3A) and a sixth layer (SL3B) alternately arranged,
the fifth layer (SL3A) is composed of Al_{z}Ga_{1-z}N, where 0<z<y,
the sixth layer (SL3B) is composed of GaN, and
the electron transit layer (24) is formed above the third superlattice buffer layer (74).

[Clause 3, FIG. 6] The nitride semiconductor device according to clause 1, where
the nitride semiconductor layer (20) further includes an upper buffer layer (74) arranged between the second superlattice buffer layer (72) and the electron transit layer (24), and
the upper buffer layer (74) is composed of AlᵤGa₁₋ᵤN, where 0<u<y.

[Clause 4, FIG. 7] The nitride semiconductor device according to clause 1, where
the nitride semiconductor layer (20) further includes an intermediate buffer layer (72) arranged between the first superlattice buffer layer (70) and the second superlattice buffer layer (74), and
the intermediate buffer layer (72) is composed of AlᵢGa₁₋ᵢN, where y<i<x.

[Clause 5, FIG. 8] The nitride semiconductor device according to clause 1, where
the nitride semiconductor layer (20) further includes a lower buffer layer (70) arranged between the semiconductor substrate (18) and the first superlattice buffer layer (72), and
the lower buffer layer (70) is composed of Al_{b}Ga_{1-b}N, where x<b<1.

[Clause 6] The nitride semiconductor device according to any one of clauses 1 to 5, where
the nitride semiconductor layer (20) further includes a base buffer layer (68) in contact with the semiconductor substrate (18), and
the base buffer layer (68) is composed of AlN.

[Clause 7] The nitride semiconductor device according to any one of clauses 1 to 3, where the second superlattice buffer layer (72; 74; 108) is in contact with the first superlattice buffer layer (70; 72; 106).

[Clause 8] The nitride semiconductor device according to any one of clauses 1 to 7, where
the nitride semiconductor layer (20) includes a bottom surface (20B) in contact with the semiconductor substrate (18) and includes dislocation lines, and
in a region below the at least one electrode (32, 36, 38), a number of dislocation lines extending in an interface between the electron transit layer (24) and the electron supply layer (26) is less than a number of dislocation lines extending from the bottom surface (20B) of the nitride semiconductor layer (20).

[Clause 9] The nitride semiconductor device according to any one of clauses 1 to 8, where the first superlattice structure (SL1) includes a two-layer structure that is formed of the first layer (SL1A) and the second layer (SL1B) and repeats between two times and five hundred times, inclusive.

[Clause 10] The nitride semiconductor device according to any one of clauses 1 to 9, where
the first nitride semiconductor includes GaN, and
the second nitride semiconductor includes AlGaN.

[Clause 11] The nitride semiconductor device according to any one of clauses 1 to 10, where the semiconductor substrate (18) is composed of a material that differs from the nitride semiconductor layer (20).

[Clause 12] The nitride semiconductor device according to any one of clauses 1 to 11, where the semiconductor substrate (18) is a silicon (Si) substrate having a (111) growth surface.

[Clause 13] The nitride semiconductor device according to any one of clauses 1 to 12, where the semiconductor substrate (18) has an off-angle that is greater than 0° and less than or equal to 1°.

[Clause 14] The nitride semiconductor device according to any one of clauses 1 to 13, where
the first layer (SL1A) has a thickness that is in a range of 5 nm to 7 nm, and
the second layer (SL1B) has a thickness that is in a range of 2 nm to 3 nm.

[Clause 15] The nitride semiconductor device according to any one of clauses 1 to 14, where the first superlattice buffer layer (70; 72; 106) has a thickness that is greater than or equal to 100 nm.

[Clause 16] The nitride semiconductor device according to any one of clauses 1 to 15, where the electron transit layer (24) has a thickness that is less than or equal to 760 nm.

[Clause 17] The nitride semiconductor device according to any one of clauses 1 to 16, where
the nitride semiconductor layer (20) further includes a gate layer (30) formed above the electron supply layer (26), and
the gate layer (30) is composed of a third nitride semiconductor containing an acceptor impurity.

[Clause 18] The nitride semiconductor device according to clause 17, where the third nitride semiconductor includes GaN.

[Clause 19] The nitride semiconductor device according to any one of clauses 1 to 18, where the first superlattice buffer layer (70; 72; 106) includes at least one of Fe, C, and Si as an impurity.

[Clause 20] The nitride semiconductor device according to any one of clauses 1 to 19, where x satisfies that 0.35<x<0.9, and y satisfies that 0.1<y<0.65.

[Clause 21] The nitride semiconductor device according to any one of clauses 1 to 20, where the second superlattice structure (SL2) includes a two-layer structure that is formed of the third layer (SL2A) and the fourth layer (SL2B) and repeats between two times and five hundred times, inclusive.

[Clause 22] The nitride semiconductor device according to any one of clauses 1 to 21, where
the third layer (SL2A) has a thickness that is in a range of 5 nm to 7 nm, and
the fourth layer (SL2B) has a thickness that is in a range of 2 nm to 3 nm.

[Clause 23] The nitride semiconductor device according to any one of clauses 1 to 22, where the second superlattice buffer layer (72; 74; 108) has a thickness that is greater than or equal to 100 nm.

[Clause 24] The nitride semiconductor device according to any one of clauses 1 to 23, where the second superlattice buffer layer (72; 74; 108) includes at least one of Fe, C, and Si as an impurity.

[Clause 25] The nitride semiconductor device according to clause 2, where the third superlattice structure (SL3) includes a two-layer structure that is formed of the fifth layer (SL3A) and the sixth layer (SL3B) and repeats between two times and five hundred times, inclusive.

[Clause 26] The nitride semiconductor device according to clause 2 or 25, where
the fifth layer (SL3A) has a thickness that is in a range of 5 nm to 7 nm, and
the sixth layer (SL3B) has a thickness that is in a range of 2 nm to 3 nm.

[Clause 27] The nitride semiconductor device according to any one of clauses 2, 25, and 26, where the third superlattice buffer layer (74) has a thickness that is greater than or equal to 100 nm.

[Clause 28] The nitride semiconductor device according to any one of clauses 2 and 25 to 27, where the third superlattice buffer layer (74) includes at least one of Fe, C, and Si as an impurity.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A nitride semiconductor device, comprising:
a semiconductor substrate;
a nitride semiconductor layer formed above the semiconductor substrate; and
at least one electrode formed above the nitride semiconductor layer, wherein
the nitride semiconductor layer includes
a first superlattice buffer layer,
a second superlattice buffer layer formed above the first superlattice buffer layer,
an electron transit layer formed above the second superlattice buffer layer and composed of a first nitride semiconductor, and
an electron supply layer formed above the electron transit layer and composed of a second nitride semiconductor having a larger bandgap than the first nitride semiconductor,
the first superlattice buffer layer has a first superlattice structure including a first layer and a second layer that are alternately arranged,
the first layer is composed of AlₓGa₁₋ₓN, where 0<x<1,
the second layer is composed of GaN,
the second superlattice buffer layer has a second superlattice structure including a third layer and a fourth layer that are alternately arranged,
the third layer is composed of Al_{y}Ga_{1-y}N, where 0<y<x, and
the fourth layer is composed of GaN.

2. The nitride semiconductor device according to claim 1, wherein
the nitride semiconductor layer further includes a third superlattice buffer layer formed above the second superlattice buffer layer,
the third superlattice buffer layer has a third superlattice structure including a fifth layer and a sixth layer alternately arranged,
the fifth layer is composed of Al_{z}Ga_{1-z}N, where 0<z<y,
the sixth layer is composed of GaN, and
the electron transit layer is formed above the third superlattice buffer layer.

3. The nitride semiconductor device according to claim 1, wherein
the nitride semiconductor layer further includes an upper buffer layer arranged between the second superlattice buffer layer and the electron transit layer, and
the upper buffer layer is composed of AlᵤGa₁₋ᵤN, where 0<u<y.

4. The nitride semiconductor device according to claim 1, wherein
the nitride semiconductor layer further includes an intermediate buffer layer arranged between the first superlattice buffer layer and the second superlattice buffer layer, and
the intermediate buffer layer is composed of AlᵢGa₁₋ᵢN, where y<i<x.

5. The nitride semiconductor device according to claim 1, wherein
the nitride semiconductor layer further includes a lower buffer layer arranged between the semiconductor substrate and the first superlattice buffer layer, and
the lower buffer layer is composed of Al_{b}Ga_{1-b}N, where x<b<1.

6. The nitride semiconductor device according to claim 1, wherein
the nitride semiconductor layer further includes a base buffer layer in contact with the semiconductor substrate, and
the base buffer layer is composed of AlN.

7. The nitride semiconductor device according to claim 1, wherein the second superlattice buffer layer is in contact with the first superlattice buffer layer.

8. The nitride semiconductor device according to claim 1, wherein
the nitride semiconductor layer includes a bottom surface in contact with the semiconductor substrate and includes dislocation lines, and
in a region below the at least one electrode, a number of dislocation lines extending in an interface between the electron transit layer and the electron supply layer is less than a number of dislocation lines extending from the bottom surface of the nitride semiconductor layer.

9. The nitride semiconductor device according to claim 1, wherein the first superlattice structure includes a two-layer structure that is formed of the first layer and the second layer and repeats between two times and five hundred times, inclusive.

10. The nitride semiconductor device according to claim 1, wherein
the first nitride semiconductor includes GaN, and
the second nitride semiconductor includes AlGaN.

11. The nitride semiconductor device according to claim 1, wherein the semiconductor substrate is composed of a material that differs from the nitride semiconductor layer.

12. The nitride semiconductor device according to claim 1, wherein the semiconductor substrate is a silicon substrate having a growth surface.

13. The nitride semiconductor device according to claim 1, wherein the semiconductor substrate has an off-angle that is greater than 0° and less than or equal to 1°.

14. The nitride semiconductor device according to claim 1, wherein
the first layer has a thickness that is in a range of 5 nm to 7 nm, and
the second layer has a thickness that is in a range of 2 nm to 3 nm.

15. The nitride semiconductor device according to claim 1, wherein the first superlattice buffer layer has a thickness that is greater than or equal to 100 nm.

16. The nitride semiconductor device according to claim 1, wherein the electron transit layer has a thickness that is less than or equal to 760 nm.

17. The nitride semiconductor device according to claim 1, wherein
the nitride semiconductor layer further includes a gate layer formed above the electron supply layer, and
the gate layer is composed of a third nitride semiconductor containing an acceptor impurity.

18. The nitride semiconductor device according to claim 17, wherein the third nitride semiconductor includes GaN.

19. The nitride semiconductor device according to claim 1, wherein the first superlattice buffer layer includes at least one of Fe, C, and Si as an impurity.

20. The nitride semiconductor device according to claim 1, wherein x satisfies that 0.35<x<0.9, and y satisfies that 0.1<y<0.65.
